(19) United States
(12) Patent Application Publication
(10) Pub. No.: US 2009/0146745 A1
(43) Pub. Date: Jun. 11, 2009

(54) NOISE REDUCING DIELECTRIC RESONATOR OSCILLATOR

(75) Inventors: Deborah S. Dendy, Tempe, AZ (US); Dean L. Cook, Mesa, AZ (US); Kenneth V. Buer, Gilbert, AZ (US)

Correspondence Address: SNELL & WILMER L.L.P. (Main), 400 EAST VAN BUREN, ONE ARIZONA CENTER, PHOENIX, AZ, 85004-2202, US

(73) Assignee: VIASAT, INC., Carlsbad, CA (US)

(21) Appl. No.: 11/950,575

(22) Filed: Dec. 5, 2007

(51) Int. Cl. H03B 1/00

(52) U.S. Cl. 331/68

(57) ABSTRACT

Systems, devices, and methods are provided for reducing noise in communication systems. An example resonator system comprises: a housing comprising a top portion and a floor portion, a dielectric resonator positioned with the housing, a substrate, and a stripline transmission line adjacent the substrate. In this exemplary embodiment, the stripline transmission line within the housing is electromagnetically coupled to the dielectric resonator, the substrate is positioned away from the floor portion and top portion of the housing, and the dielectric resonator coupled with the suspended stripline transmission line is connected to an active device to form an oscillator. The positioning of the substrate relative to the housing may reduce the amount of the electromagnetic field from the stripline transmission line that is absorbed into the housing. In a further embodiment, the board has no metallic backing on at least a portion of the back of the board.

### FIELD

The subject of this disclosure may relate generally to systems, devices, and methods for reducing noise in a dielectric oscillating system, particularly in communication systems.

### BACKGROUND

It is desirable to reduce loss, phase noise, and/or signal attenuation in communication systems. The quality factor, or Q, of the system is inversely proportional to the loss. One type of communication system utilizes dielectric resonating oscillators. Dielectric resonating oscillators may utilize a dielectric puck coupled with a microstrip transmission line element as a tank circuit for creating the conditions necessary for oscillation. The dielectric resonator may have a relatively high Q, such as in the range of 10,000. The combination of the microstrip circuitry and dielectric resonator puck may have a relatively low Q as compared to the dielectric resonator by itself. Since the lower Q increases the phase noise of the system, it is desirable to find a method to increase the Q of the circuitry coupled with the dielectric resonator and therefore lower the phase noise of the oscillator system.

### SUMMARY

In exemplary embodiments, systems, devices, and methods for lowering loss and increasing Q in a dielectric resonator oscillating system are described. In an exemplary embodiment, a circuit board with a stripline transmission line is positioned with an air gap between the board and the housing. This may reduce the amount of electromagnetic fields from the stripline that are absorbed into the housing and/or a metallic backing on the board.

In accordance with another exemplary embodiment, the board may be elevated off the floor of the housing via a pedestal. However, other methods and systems for creating a distance between the board, or a portion thereof, and the housing may also be used in exemplary embodiments.

### BRIEF DESCRIPTION OF THE DRAWINGS

These and other features, aspects and advantages of the present invention will become better understood with reference to the following description, appending claims, and accompanying drawings where:

FIG. 1 illustrates a side elevation view of a layout of a prior art dielectric resonator system;

FIG. 2 illustrates an exemplary dielectric resonator configuration for reducing noise in a dielectric resonator oscillating system;

FIG. 3 illustrates a flow diagram of a method for generally increasing Q of a system; and

FIG. 4 illustrates another side elevation view of an exemplary dielectric resonator configuration.

### DETAILED DESCRIPTION

In accordance with an exemplary embodiment of the present invention, systems, devices, and methods are provided, for among other things, reducing noise in a dielectric oscillating system. The following descriptions are not intended as a limitation on the use or applicability of the invention, but instead, are provided merely to enable a full and complete description of exemplary embodiments.

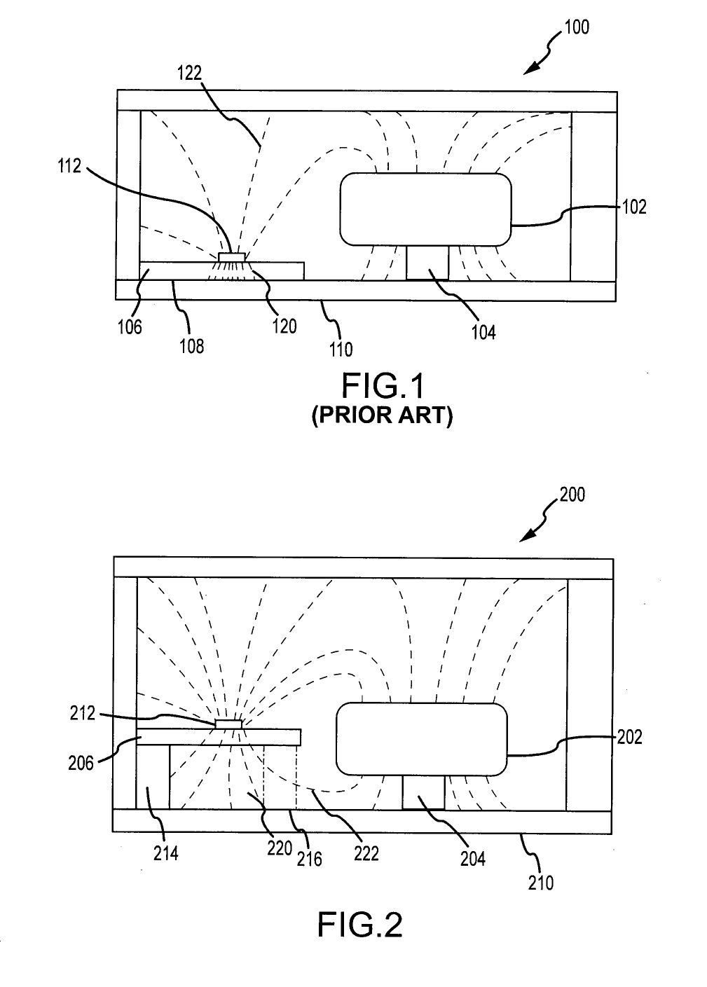

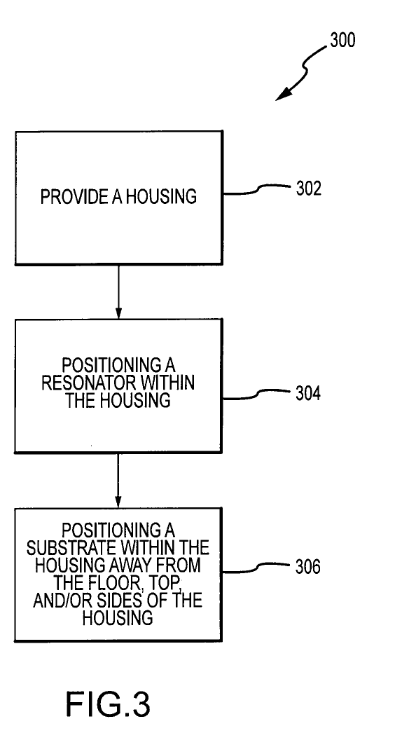

FIG. 1 shows a prior art dielectric resonator system 100, which includes a dielectric resonator 102, a dielectric resonator support 104, housing 110, board/substrate 106, and microstrip transmission line 112. Dielectric resonator 102 is supported and positioned somewhat away from housing 110 via support 104. Support 104 is made of a lower dielectric constant material. Support 104 is configured to physically stabilize the dielectric resonator 102.

Board 106 typically includes a backing 108. Backing 108 includes a metallic substance. Microstrip 112 is coupled to and/or located adjacent board 106. As shown, board 106 physically contacts housing 110.

FIG. 1 also illustrates electromagnetic field lines 120 and 122. Field lines include absorbed field lines 120, as well as unabsorbed field lines 122. As can be seen, the field lines, may be absorbed by backing 108, as well as housing 110. It will be appreciated that backing 108, as well as housing 110, may include metallic materials such that field lines would be absorbed within the metal. The more field lines that are absorbed, the lower the Q and higher the loss and phase noise of the overall system.

With reference now to FIG. 2, and in accordance with an exemplary embodiment of the present invention, a system 200 is provided for, among other things, reducing noise in a dielectric oscillating system. In this exemplary embodiment, system 200 comprises a housing 210, a dielectric resonator 202, a dielectric resonator support member 204, a board/substrate 206, and stripline transmission line 212. Furthermore, an exemplary embodiment may comprise a substrate support member 214.

Continuing with this exemplary embodiment, dielectric resonator 202 is located within housing 210 and connected to housing 210 by dielectric resonator support member 204. Furthermore, substrate 206 also is located within housing 210 and is located near dielectric resonator 202. In particular, substrate 206 is located within housing 210 spaced apart from the bottom and top of housing 210. Substrate 206 may be connected, for example, to housing 210 via substrate support member 214.

In an exemplary embodiment, housing 210 includes a top, a floor and at least one side. A cavity and/or vessel is formed therein and may be configured to contain dielectric resonator 202. Housing 210 may be constructed from various materials, including but not limited to, plastics, composites, metals, and/or other material, and/or combinations thereof. Furthermore, housing 210 may be may formed of any material suitable for forming an enclosure.

In an exemplary embodiment, dielectric resonator 202 is supported and positioned somewhat away from housing 210 via support member 204. In one exemplary embodiment, dielectric resonator 202 is approximately puck shaped. However, dielectric resonator 202 may be any shape suitable to function as a dielectric resonator.

In accordance with an exemplary embodiment, dielectric resonator 202 may comprise a dielectric material. However, other materials and/or combination of materials may be utilized without straying from the concepts disclosed herein. In another exemplary embodiment, dielectric resonator 202 comprises ceramic material of high dielectric constant. For example, the dielectric constant may be configured to be approximately 36. However, in other embodiments, the dielectric constant may be approximately 18 or higher. The size of the dielectric resonator may depend at least in part upon the desired frequency of the oscillator. In one embodiment, for high frequencies, the dielectric resonator would be smaller than at lower frequencies.

In an exemplary embodiment, dielectric resonator support member 204 is physically connected to dielectric resonator 202 and to housing 210. Support member 204 is configured to physically stabilize the dielectric resonator 202 and/or generally provide separation of dielectric resonator 202 from housing 210. In an exemplary embodiment, support member 204 is made of a lower dielectric constant material. However, support member 204 may be made of any suitable materials and/or combination of materials.

Substrate 206 may comprise any suitable structure configured, for example, to support stripline transmission line 212. In one exemplary embodiment, substrate 206 comprises a board, such as a printed wiring circuit board. In accordance with an exemplary embodiment of the present invention, substrate 206 is positioned within housing 210 such that some space exists between substrate 206 (or a portion thereof) and the floor and top of housing 210. In an exemplary embodiment, substrate 206 is supported in a position apart from the floor and top of housing 210 via substrate support member 214. Thus, system 200 may be configured to position substrate 206 in such a manner as to form a cavity 220 between housing 210 and substrate 206.

In one exemplary embodiment, cavity 220 is filled with air. The air filled cavity may be configured to reduce the loss of the stripline transmission line and therefore increase the Q of system 200. Nevertheless, in accordance with other exemplary embodiments, cavity 220 may be filled with other materials, such as a dielectric material, and/or any material which may generally reduce the amount of electromagnetic field absorbed.

In accordance with various exemplary embodiments, board/substrate 206 may not include a metal backing. The metal backing may be absent from the entire board/substrate or a portion thereof. The absence of the metal backing (or a portion thereof) may increase the Q of board/substrate 206, and/or overall system 200. In particular, the metal backing may be absent from board/substrate 206 in the proximity of stripline transmission line 212. In one embodiment, the metal backing is removed from the entire board/substrate 206, or a portion thereof. In another embodiment, the metal backing is not added to board/substrate 206 to begin with. Adding a metal backing to a substrate may increase costs, as well as time, to produce substrate 206. Therefore, not having a metal backing may reduce manufacturing time and costs, among other considerations.

In an exemplary embodiment, system 200 includes stripline transmission line 212. Stripline transmission line 212 may be adjacent board/substrate 206. In an exemplary embodiment, stripline transmission line 212 may be electromagnetically coupled to dielectric resonator 202.

The embodiment described with reference to FIG. 2 is a system embodying serial feedback; however, it will be appreciated that other configurations may be utilized, including a parallel feedback system. Furthermore, in other exemplary embodiments, more than one stripline(s) are coupled to dielectric resonator 202.

Because the stripline transmission line 212 is located on or adjacent to substrate/board 206, and because substrate/board 206 is suspended, the stripline transmission line(s) is and may be referred to herein as a suspended stripline(s). The suspended stripline(s) are thus configured to have lower power loss, lower insertion loss, lower phase loss and/or other lower losses and/or combinations thereof. Some and/or all of these lower losses may lead to a higher Q for the stripline 212 and, therefore, may lead to a higher Q of the overall system.

As mentioned above, substrate/board 206 and the associated stripline transmission line(s) 212 may be suspended using any number of techniques. For example, substrate/board 206 may be suspended, in a cantilever manner, by a substrate support member 214. Substrate support member 214 may, for example, comprise a pedestal coupled to one side of substrate/board 206, and coupled to a side and/or floor of housing 210. In one exemplary embodiment, substrate support member 214 may be approximately 25% of the length of substrate/board 206, and may be approximately as tall as it is long. In other exemplary embodiments, substrate support member 214 may have any suitable dimensions smaller than and/or larger than the substrate 206, which it supports. Thus, substrate support member may comprise any suitable dimensions and/or configurations that are configured to position substrate/board 206 (and stripline transmission line 212) away from housing 210.

In other exemplary embodiments, more than one support may be utilized. For example, system 200 may comprise a second substrate support member 216, which may also be configured to position substrate/board 206 away from housing 210. In this regard then, any suitable number of substrate support members may be used.

In accordance with various other exemplary embodiments, other configurations for positioning substrate 206 away from the top, floor, and/or sides of housing 210 may be utilized. For example, substrate 206 may be cantilevered from the side of housing 210. In another exemplary embodiment, system 200 may be configured to suspend substrate 206 from one or more sides of housing 210. In another exemplary embodiment, system 200 may be configured to suspend substrate 206 from the top of housing 210. Furthermore, substrate 206 may be suspended on top of another substrate, on top of a support, mounted directly to the side of the housing, and/or other configurations and/or combinations thereof.

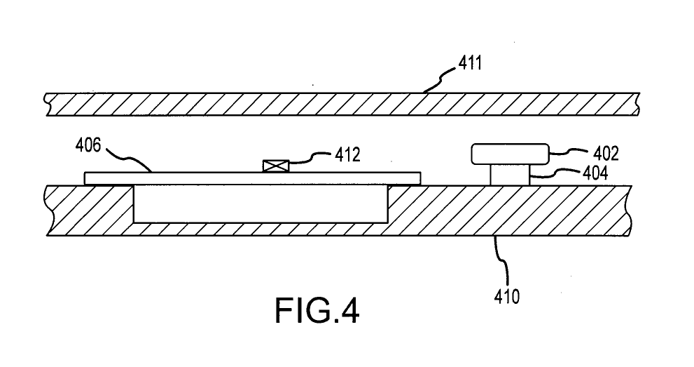

With momentary reference now to FIG. 4, in accordance with yet another exemplary embodiment of the present invention, substrate 206 is “suspended” by dropping a portion of the housing to create a space or cavity beneath substrate 206. Thus, in one exemplary embodiment, a system 400 comprises a housing bottom 410 and housing top 411, a dielectric resonator 402 connected to housing bottom 410 by a dielectric resonator support member 404, and a substrate 406 supporting a stripline transmission line 412. In this exemplary embodiment, substrate 406 is in contact with housing bottom 410 and in this sense is not raised. Nevertheless, housing bottom 410 has been etched, carved out, or otherwise formed so as to have a cavity or space beneath substrate 406 or a portion thereof. In this exemplary embodiment, the back of substrate 406 may have the metal etched from the board in, for example, the area that is not in contact with housing bottom 410.

Furthermore, the resonator system may be configured in many other ways to position substrate 206, or at least a portion thereof, such that some portion of substrate 206 has a space above and beneath the substrate. Stated another way, many different configurations may be utilized to position substrate 206 somewhat away from the top and bottom of housing 210. Thus, a suspended stripline transmission line, in an exemplary embodiment, is any conductor located between a housing top and a housing bottom such that respective spaces exist between the conductor and the housing top and the housing bottom. Although this space may be filled with air, it may also be filled with other dielectric materials.

As used herein, a microstrip generally refers to a conductor near or adjacent a single ground plane. In contrast, a stripline transmission line is a conductor associated with two or more ground planes; typically one above and one below.

Substrate support member 214 may be made of a dielectric material, as well as many other materials, and/or combination of materials, which may be configured to generally increase Q of the system.

In an exemplary embodiment, substrate 206 may be adjacent to the substrate support member(s) 214 and 216. Furthermore, substrate 206 may be generally secured to the substrate support member(s) 214 and 216 via adhesive, screw, interference fit, and/or any other methods and systems and/or combinations thereof, for generally securing substrate 206 to substrate support member(s) 214 and 216. Other methods of adhering substrate 206 to support member(s) 214 and 216 may include utilizing epoxy, teflon-type and/or teflon-coated screw, and/or other materials and methods. Similar securing mechanisms as described herein may also be used to secure substrate 206 directly to housing 210.

With reference again to FIG. 2, the dielectric resonator and stripline transmission line may create electromagnetic field lines 222. In accordance with an exemplary embodiment, the system 200 is configured such that fewer field lines are absorbed by the board backing and/or the housing than would be absorbed in a system with a transmission line that is not suspended. This reduction of absorbed field lines may be based at least in part upon the substrate 206 not having a metal backing. This reduction may also be based in part upon the positioning of substrate 206 away from the housing 210. This positioning may reduce the amount of field, which may be absorbed by the substrate backing, and/or the housing. Moreover, to further reduce absorption of the field, housing 210 may be made from materials other than metals, and/or a coating may be applied to portions of housing 210 to reduce absorption of the magnetic field.

Thus, system 200 may be configured to reduce the absorption of the electromagnetic field from stripline transmission line 212 and to thus increase the Q of the stripline. In this exemplary embodiment, the suspended stripline transmission line described with reference to FIG. 2 may be configured to have a higher Q than the microstrip 112 described with reference to FIG. 1.

Thus, system 200 may be configured to have a higher Q for the stripline transmission line than for a microstrip of similar functionality; and therefore system 200 may be configured to increase the Q of the overall system. Because Q is inversely proportional to loss, increasing Q may also reduce loss of the overall system as compared to a system without a suspended stripline transmission line. Similarly, system 200 may be configured to have a lower phase noise compared to a system without a suspended stripline transmission line. Further still, system 200 may be configured to have a higher bit rate, and lower bit error rate compared to a system without a suspended stripline transmission line. This is so because the higher the noise and lower the Q, the higher the bit error rate may be.

Increasing the Q of the stripline transmission line may have the added benefit of making the dielectric resonator oscillator system less expensive to build. For example, in one embodiment substrate 206 does not have any metal backing, saving manufacturing time and costs associated with adding such a metal backing.

In accordance with another aspect of the present invention, system 200 may be configured to achieve the same performance (in terms of noise, bit rate, and/or bit error rate) as obtained by a microstrip system, but to do so much less expensively. This is the case because raising the Q associated with the stripline transmission line facilitates lowering the Q of the puck without degrading the overall Q of the dielectric resonator oscillator. Because high Q pucks are expensive, in one aspect of the present invention, then, a less expensive dielectric resonator oscillator may be built using less expensive pucks but still achieving the same performance by suspending the stripline transmission line.

In accordance with an exemplary embodiment of the present invention, system 200 is configured to be connected to an active component to form an oscillator. In an exemplary embodiment, the resonator is attached to any active component such as a field effect transistor, a bipolar transistor, or any other type of active element which under specific operating conditions can be induced to oscillate. By way of example, such combined systems may include: communication systems, receivers, transmitters, and/or other systems or devices and/or combinations thereof. In another exemplary embodiment, the stripline transmission line may be connected to a load and/or other circuitry to create an oscillator.

In prior art dielectric resonator oscillators (DROs), a microstrip transmission line is coupled to a dielectric resonator as the tank circuit for oscillation. In contrast, the benefit of using suspended stripline transmission line coupled to the dielectric resonator is that the losses are lower than for the microstrip line coupled to the resonator. Lower loss yields higher Q and lower phase noise in the overall oscillator. This is a improvement in overall system performance as it leads to lower bit error rate.

In accordance with another exemplary embodiment, system 200 may also be utilized as a filter structure having low loss properties. Although also forming an oscillator, it is noted that a tank circuit comprising an active component connected to a dielectric resonator (the dielectric resonator in communication with a suspended stripline transmission line) may serve as a filter.

In accordance with various exemplary embodiments of the present invention, a method 300 is provided for reducing noise in a dielectric oscillating system. The method 300 may include, for example, providing a housing (step 302), coupling the resonator to the housing (step 304), and positioning a substrate generally away from the floor and top of the housing (step 306).

In an exemplary embodiment, providing a housing (step 302) may include providing a housing which may include a top, floor and sides. The housing may be made of a dielectric material, metal, metal with a coating, and/or other materials, and/or combinations thereof. The housing may be similar to existing housings now used or hereafter designed.

Method 300 may include positioning a resonator within the housing (step 304). The resonator may be positioned and/or coupled adjacent the housing. The resonator may be coupled directly to the housing and/or via a dielectric support member. In an exemplary embodiment, the resonator may physically reside within the housing, not touching the walls, top, or floor of the housing within the space interior to the housing.

Method 300 may also include positioning a substrate within the housing generally away from the floor and top of the housing (step 306). In this manner, there may be a cavity created between the substrate and the housing, such that less electromagnetic field waves from a stripline on the substrate may be absorbed. The cavity may be filled with air. However, other materials, such as a dielectric material, may be positioned in the cavity to reduce the amount of electromagnetic field absorbed (compared to an embodiment with a microstrip adjacent to the housing). The substrate and stripline may be positioned a distance away from the resonator, depending upon the design of the system, to achieve different results.

In the following description and/or claims, the terms coupled and/or connected, along with their derivatives, may be used. In particular embodiments, connected may be used to indicate that two or more elements are in direct physical and/or electrical contact with each other. Coupled may mean that two or more elements are in direct physical and/or electrical contact. However, coupled may also mean that two or more elements may not be in direct contact with each other, but yet may still cooperate and/or interact with each other. Furthermore, couple may mean that two objects are in communication with each other, and/or communicate with each other, such as two pieces of hardware. Furthermore, the term “and/or” may mean “and”, it may mean “or”, it may mean “exclusive-or”, it may mean “one”, it may mean “some, but not all”, it may mean “neither”, and/or it may mean “both”, although the scope of claimed subject matter is not limited in this respect.

It should be appreciated that the particular implementations shown and described herein are illustrative of various embodiments including its best mode, and are not intended to limit the scope of the present disclosure in any way. For the sake of brevity, conventional techniques for signal processing, data transmission, signaling, and network control, and other functional aspects of the systems (and components of the individual operating components of the systems) may not be described in detail herein. Furthermore, the connecting lines shown in the various figures contained herein are intended to represent exemplary functional relationships and/or physical couplings between the various elements. It should be noted that many alternative or additional functional relationships or physical connections may be present in a practical communication system.

While the principles of the disclosure have been shown in embodiments, many modifications of structure, arrangements, proportions, the elements, materials and components, used in practice, which are particularly adapted for a specific environment and operating requirements without departing from the principles and scope of this disclosure. These and other changes or modifications are intended to be included within the scope of the present disclosure and may be expressed in the following claims.

What is claimed is:

1. A resonator system, comprising:
a housing comprising a top portion and a floor portion;
a dielectric resonator positioned with the housing;
a substrate; and
a stripline transmission line adjacent the substrate, wherein the stripline transmission line and substrate are positioned within the housing, wherein the stripline transmission line is electromagnetically coupled to the dielectric resonator, wherein the substrate is positioned away from the floor portion and top portion of the housing, and wherein the dielectric resonator coupled with the suspended stripline transmission line is connected to an active device to form an oscillator.

2. The resonator system according to claim 1, wherein the stripline transmission line is coupled to the dielectric resonator via electromagnetic field.

3. The resonator system according to claim 2, wherein the substrate does not include a metallic backing.

4. The resonator system according to claim 3, wherein the amount of the electro-magnetic field absorbed by the metallic backing and/or the housing is reduced compared to a system comprising a microstrip in proximity to the housing with otherwise similar performance.

5. The resonator system according to claim 1, wherein the system is utilized as a filter.

6. The resonator system according to claim 1, wherein the Q of the puck may be reduced compared to the Q of a system comprising a microstrip that is in proximity to the housing, but wherein the performance quality of the resonator system is not reduced.

7. The resonator system according to claim 1, wherein the substrate is supported generally away from the housing at least in part by a support member.

8. The resonator system according to claim 7, wherein the support member has a different dielectric constant than a dielectric constant of the dielectric resonator.

9. The resonator system according to claim 7, wherein the substrate is mechanically coupled to the support member.

10. The resonator system according to claim 7, wherein the substrate is formed integrally with the support member.

11. The resonator system according to claim 1, wherein the substrate is coupled to a wall of the housing, so as to form a cavity between the substrate and both a floor and a top of the housing.

12. The resonator system according to claim 11, wherein air is included within the cavity.

13. The resonator system according to claim 12, wherein a dielectric material is included within the cavity.

14. A method of reducing loss in an oscillator system, comprising:
providing a housing comprising a floor and a top;
positioning a dielectric resonator in the housing;
positioning a substrate, comprising a stripline transmission line, away from the floor of the housing and away from the top of the housing, thereby creating a first cavity between the floor and the substrate and a second cavity between the top of the housing and the substrate, wherein the stripline transmission line and dielectric resonator form a dielectric resonator system; and
connecting the dielectric resonator system to an active component to form an oscillator.

15. The method according to claim 14, wherein positioning the dielectric resonator comprises coupling the dielectric resonator to the housing at least in part via a dielectric support member.

16. The method according to claim 14, wherein positioning the substrate comprises mechanically coupling the substrate to the housing at least in part via a substrate support member.

17. The method according to claim 14, wherein positioning the substrate comprises forming at least a portion of the housing to have a cut-away portion that is configured to create a cavity below a portion of the substrate when the substrate is attached to the housing.

18. The method according to claim 14, wherein positioning the substrate comprises coupling the substrate to the wall of the housing, generally apart from the floor and/or top of the housing.

19. A dielectric resonator comprising:
a housing comprising a housing top portion and a housing bottom portion, wherein the housing bottom portion further comprises a recess;
a dielectric resonator positioned within the housing;
a substrate;
a stripline transmission line, wherein the stripline transmission line is located on a first side of the substrate, wherein the stripline transmission line is coupled electromagnetically to the dielectric resonator, and wherein the recess is configured to create a cavity between the stripline transmission line and the housing bottom when the stripline transmission line is installed in the housing, and wherein the cavity is located under at least a portion of the stripline transmission line when the stripline transmission line is installed in the housing; and
an active component, wherein the active component is configured to oscillate when electromagnetically coupled to the dielectric resonator.

20. The dielectric resonator of claim 19, the substrate further comprising a second side opposite the first side, wherein the substrate has no metal on at least a portion of the second side, and wherein the cavity is filled with air.
